(19) United States
(12) Patent Application Publication
(10) Pub. No.: US 2019/0018085 A1
(43) Pub. Date: Jan. 17, 2019

(54) MAGNETOMETER WITH THERMAL ELECTRIC COOLING OF THE EXCITATION LIGHT SOURCE

(71) Applicant: LOCKHEED MARTIN CORPORATION, Bethesda, MD (US)

(72) Inventors: Cedric H. WU, Bethesda (US); Joseph W. HAHN, Bethesda (US); Yongdan HU, Bethesda (US); Kenneth M. JACKSON, Bethesda (US)

(73) Assignee: LOCKHEED MARTIN CORPORATION, Bethesda, MD (US)

(21) Appl. No.: 16/031,065

(22) Filed: Jul. 10, 2018

Related U.S. Application Data
(60) Provisional application No. 62/531,352, filed on Jul. 11, 2017.

(51) Int. Cl. G01R 33/26; G01R 33/32

(52) U.S. Cl. CPC G01R 33/26; G01R 33/323

(57) ABSTRACT

A system for magnetic detection is described. The system includes a magneto-optical defect center material including a plurality of magneto-optical defect centers, an RF excitation source, an optical excitation source assembly including an optical excitation source, a system controller, and an optical detector. The system controller is configured to control the RF excitation source to provide RF excitation to the magneto-optical defect center material, and control the optical excitation source to provide optical excitation to the magneto-optical defect center material. The optical detector is configured to receive an optical signal based on light emitted by the magneto-optical defect center material due to the RF excitation and the optical excitation provided to the magneto-optical defect center material. The optical excitation source assembly includes an active cooling element arranged to actively cool the optical excitation source without cooling the RF excitation source, the magneto-optical defect center material, or the optical detector.

### CROSS-REFERENCE TO RELATED PATENT APPLICATION

The present application claims the benefit of priority from U.S. Provisional Patent Application No. 62/531,352, filed Jul. 11, 2017, which is incorporated herein by reference in its entirety.

### FIELD

The present disclosure generally relates to magnetic detection systems with thermal electric cooling, and more particularly, to thermal electric cooling of the light source of the magnetic detection system.

### BACKGROUND

Many advanced magnetic detection (such as imaging) systems can operate in limited conditions, for example, high vacuum and/or cryogenic temperatures, which can make them inapplicable for applications that require ambient conditions. Small size, weight and power (SWAP) magnetic sensors of moderate sensitivity, vector accuracy, and bandwidth are likewise deficient for certain detection (such as imaging) applications.

### SUMMARY

According to some embodiments, there is provided a system for magnetic detection of an external magnetic field. The system for magnetic detection may comprise: a magneto-optical defect center material comprising a plurality of magneto-optical defect centers; a radio frequency (RF) excitation source; an optical excitation source assembly comprising an optical excitation source; a system controller configured to: control the RF excitation source to provide RF excitation to the magneto-optical defect center material; and control the optical excitation source to provide optical excitation to the magneto-optical defect center material; and an optical detector configured to receive an optical signal based on light emitted by the magneto-optical defect center material due to the RF excitation and the optical excitation provided to the magneto-optical defect center material, wherein the optical excitation source assembly may comprise an active cooling element arranged to actively cool the optical excitation source in isolation without actively cooling the RF excitation source, the magneto-optical defect center material, or the optical detector.

According to an aspect of some embodiments, the optical excitation source may comprise a laser.

According to an aspect of some embodiments, the magneto-optical defect center material comprising a diamond nitrogen vacancy material comprising a plurality of nitrogen vacancy defect centers.

According to an aspect of some embodiments, the RF excitation source, the magneto-optical defect center material, and the optical detector are not arranged to be cooled by any active cooling element.

According to an aspect of some embodiments, the system further may comprise a frame, wherein the optical excitation source assembly, the RF excitation source, the magneto-optical defect center material, and the optical detector, are all supported on the frame.

According to an aspect of some embodiments, the system further may comprise a thermal strap connecting the optical excitation source assembly and the frame.

According to an aspect of some embodiments, the active cooling element may comprise a thermal electric cooler.

According to an aspect of some embodiments, the optical excitation source assembly further may comprise an upper heat conducting plate, wherein the optical excitation source may be mounted on, and in thermal contact with, one side of the upper heating conducting plate, and a cooling side of the active cooling element may be in thermal contact with an other side of the upper heating conducting plate.

According to an aspect of some embodiments, the upper heat conducting plate may comprise a metal.

According to an aspect of some embodiments, the optical excitation source assembly further may comprise a lower heat conducting plate in thermal contact with a heat side of the active cooling element.

According to an aspect of some embodiments, the lower heat conducting plate may comprise a metal.

According to an aspect of some embodiments, the lower heat conducting plate may be thermally isolated from the upper heat conducting plate.

According to an aspect of some embodiments, the optical excitation source assembly further may comprise a thermally insulating mount enclosing the upper heat conducting plate and the active cooling element, and fixed to the lower heat conducting plate.

According to an aspect of some embodiments, the upper heat conducting plate may be thinner than the lower heat conducting plate.

According to an aspect of some embodiments, the optical excitation source assembly further may comprise one or more thermometers thermally contacting the optical excitation source.

According to an aspect of some embodiments, the one or more thermometers comprise one or more thermistors.

According to an aspect of some embodiments, the system further may comprise a temperature controller configured to receive a temperature signal from the one or more thermometers, and to control the active cooling element based on the received temperature signal.

According to an aspect of some embodiments, the temperature controller may be a proportional integral derivative (PID) controller.

According to an aspect of some embodiments, the temperature controller may be configured to control the active cooling element based on the received temperature signal to maintain the optical excitation source at a constant temperature.

According to some embodiments, a system for magnetic detection of an external magnetic field is provided. The system may comprise: a magneto-optical defect center material comprising a plurality of magneto-optical defect centers; a radio frequency (RF) excitation source; an optical excitation source assembly comprising an optical excitation source; a system controller configured to: control the RF excitation source to provide RF excitation to the magneto-optical defect center material; and control the optical excitation source to provide optical excitation to the magneto-optical defect center material; and an optical detector configured to receive an optical signal based on light emitted by the magneto-optical defect center material due to the RF excitation and the optical excitation provided to the magneto-optical defect center material, wherein the optical excitation source assembly further may comprise: a thermal electric cooler arranged to actively cool the optical excitation source without cooling the RF excitation source, the magneto-optical defect center material, or the optical detector; one or more thermometers thermally contacting the optical excitation source; and a temperature controller configured to receive a temperature signal from the one or more thermometers, and to control the thermal electric cooler based on the received temperature signal.

### BRIEF DESCRIPTION OF THE DRAWINGS

FIG. 1 illustrates one orientation of a nitrogen vacancy (NV) center in a diamond lattice.

FIG. 2 illustrates an energy level diagram showing energy levels of spin states for an NV center.

FIG. 3 illustrates a schematic diagram illustrating an NV center magnetic sensor system.

FIG. 4 is a graph illustrating the fluorescence as a function of an applied RF frequency of an NV center along a given direction for a zero magnetic field.

FIG. 5A is a schematic illustrating a Ramsey sequence of optical excitation pulses and RF excitation pulses.

FIG. 5B is a graph illustrating the fluorescence as a function of an applied RF frequency for four different NV center orientations for a non-zero magnetic field.

FIG. 6 is a schematic diagram illustrating some embodiments of a magnetic field detection system.

FIG. 7 illustrates a perspective view of some embodiments of the optical excitation source assembly.

FIG. 8 illustrates a perspective view of some embodiments of the optical excitation source assembly, with the thermally insulating mount removed to expose the upper heat conducting plate.

FIG. 9 illustrates a cross-sectional view of some embodiments of the optical excitation source assembly.

FIG. 10 is a diagram illustrating some embodiments of a magnetic field detection system.

### DETAILED DESCRIPTION

The present disclosure generally relates to magnetic detection systems, and to systems with active cooling of an optical excitation source of the system

The system includes an optical excitation source assembly which may be actively cooled by an active cooling element. Other components of the system, such as the RF excitation source, magneto-optical defect center material, and optical detector, are not cooled by the active cooling element. This reduces the thermal mass which may be cooled by the active cooling element.

Further, a temperature controller controls the temperature of the active cooling element, which may be in thermal contact with the optical excitation source. The use of a temperature controller along with the reduced thermal mass being cooled, allow for the optical excitation source to be operated with reduced temperature fluctuation and increased stability.

### The NV Center, Its Electronic Structure, and Optical and RF Interaction

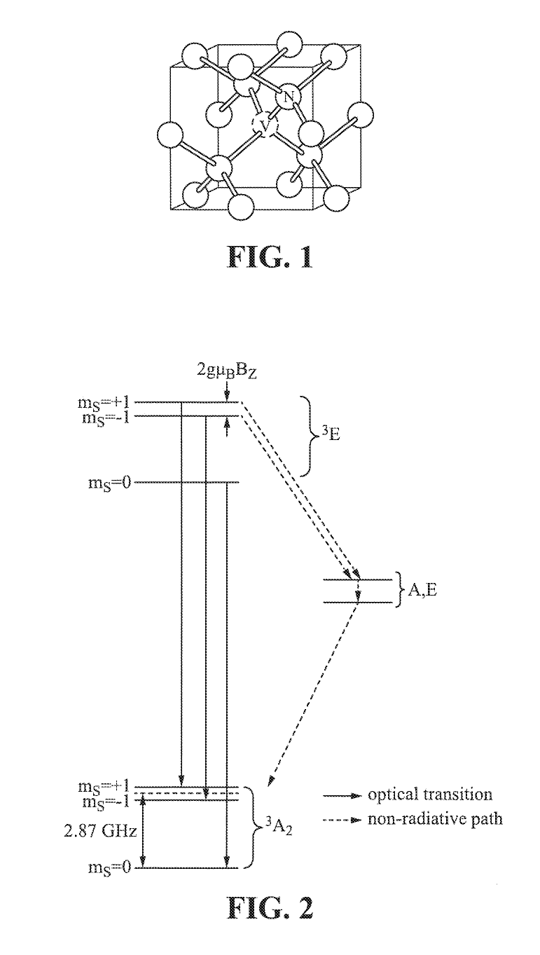

The NV center in a diamond may comprise a substitutional nitrogen atom in a lattice site adjacent a carbon vacancy as shown in FIG. 1. The NV center may have four orientations, each corresponding to a different crystallographic axis of the diamond lattice.

The NV center may exist in a neutral charge state or a negative charge state. The neutral charge state uses the nomenclature NV⁰, while the negative charge state uses the nomenclature NV.

The NV center has a number of electrons, including three unpaired electrons, each one from the vacancy to a respective of the three carbon atoms adjacent to the vacancy, and a pair of electrons between the nitrogen and the vacancy. The NV center, which may be in the negatively charged state, also includes an extra electron.

The NV center has rotational symmetry, and as shown in FIG. 2, has a ground state, which is a spin triplet with ³A₂ symmetry with one spin state mₛ=0, and two further spin states mₛ=+1, and mₛ=−1. In the absence of an external magnetic field, the mₛ=±1 energy levels are offset from the mₛ=0 due to spin-spin interactions, and the mₛ=±1 energy levels are degenerate, i.e., they have the same energy. The mₛ=0 spin state energy level is split from the mₛ=±1 energy levels by an energy of 2.87 GHz for a zero external magnetic field.

Introducing an external magnetic field with a component along the NV axis lifts the degeneracy of the mₛ=±1 energy levels, splitting the energy levels mₛ=±1 by an amount 2gμ_{B}Bz, where g is the g-factor, μ_{B} is the Bohr magneton, and Bz is the component of the external magnetic field along the NV axis. This relationship is correct to a first order and inclusion of higher order corrections is a straightforward matter and will not materially affect the computational and logic steps.

The NV center electronic structure further includes an excited triplet state ³E with corresponding mₛ=0 and mₛ=±1 spin states. The optical transitions between the ground state ³A₂ and the excited triplet ³E are predominantly spin conserving, meaning that the optical transitions are between initial and final states that have the same spin. For a direct transition between the excited triplet ³E and the ground state ³A₂, a photon of red light may be emitted with a photon energy corresponding to the energy difference between the energy levels of the transitions.

An alternative non-radiative decay route from the triplet ³E to the ground state ³A₂ via intermediate electron states exists, in which the intermediate states are thought to be intermediate singlet states A, E with intermediate energy levels. The transition rate from the mₛ=±1 spin states of the excited triplet ³E to the intermediate energy levels is significantly greater than the transition rate from the mₛ=0 spin state of the excited triplet ³E to the intermediate energy levels. The transition from the singlet states A, E to the ground state triplet ³A₂ predominantly decays to the mₛ=0 spin state over the mₛ=±1 spins states. These features of the decay from the excited triplet ³E state via the intermediate singlet states A, E to the ground state triplet ³A₂ allows that, if optical excitation is provided to the system, the optical excitation will eventually pump the NV center into the mₛ=0 spin state of the ground state ³A₂. In this way, the population of the mₛ=0 spin state of the ground state ³A₂ may be reset to a maximum polarization determined by the decay rates from the triplet ³E to the intermediate singlet states.

Another feature of the decay is that the fluorescence intensity due to optically stimulating the excited triplet ³E state is less for the mₛ=±1 states than for the mₛ=0 spin state. This is so because the decay via the intermediate states does not result in a photon emitted in the fluorescence band, and because of the greater probability that the mₛ=±1 states of the excited triplet ³E state will decay via the non-radiative decay path. The lower fluorescence intensity for the mₛ=±1 states than for the mₛ=0 spin state allows the fluorescence intensity to be used to determine the spin state. As the population of the mₛ=±1 states increases relative to the mₛ=0 spin, the overall fluorescence intensity will be reduced.

### The NV Center, or Magneto-Optical Defect Center, Magnetic Sensor System

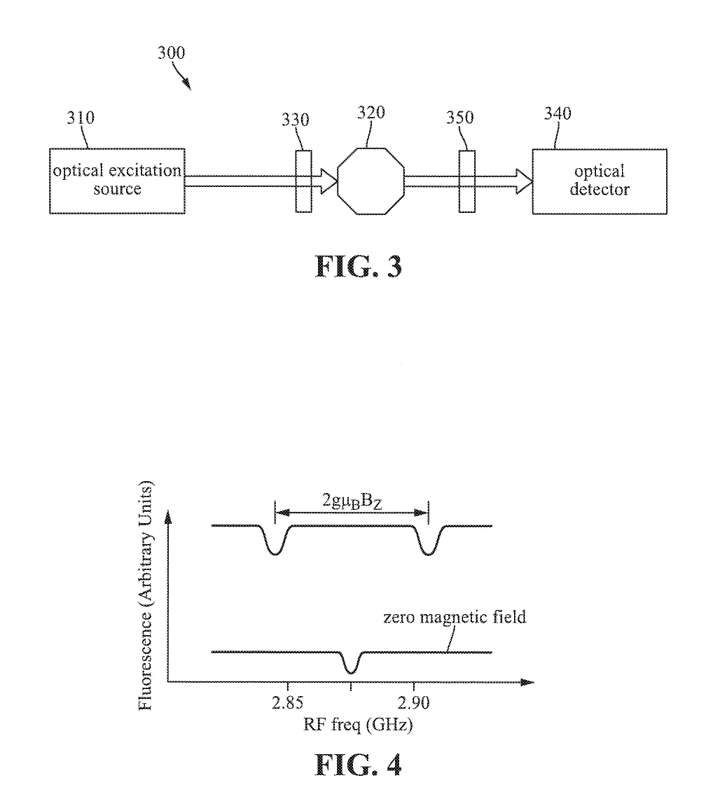

FIG. 3 is a schematic diagram illustrating an NV center magnetic sensor system 300 that uses fluorescence intensity to distinguish the mₛ=±1 states, and to measure the magnetic field based on the energy difference between the mₛ=+1 state and the mₛ=−1 state. The system 300 includes an optical excitation source 310, which directs optical excitation to an NV diamond material 320 with NV centers. The system further includes an RF excitation source 330, which provides RF radiation to the NV diamond material 320. Light from the NV diamond may be directed through an optical filter 350 to an optical detector 340.

The RF excitation source 330 may be a microwave coil, for example. The RF excitation source 330, when emitting RF radiation with a photon energy resonant with the transition energy between ground mₛ=0 spin state and the mₛ=+1 spin state, excites a transition between those spin states. For such a resonance, the spin state cycles between ground mₛ=0 spin state and the mₛ=+1 spin state, reducing the population in the mₛ=0 spin state and reducing the overall fluorescence at resonances. Similarly, resonance occurs between the mₛ=0 spin state and the mₛ=−1 spin state of the ground state when the photon energy of the RF radiation emitted by the RF excitation source is the difference in energies of the mₛ=0 spin state and the mₛ=−1 spin state, and there is a decrease in the fluorescence intensity.

The optical excitation source 310 may be a laser or a light emitting diode, for example, which emits light in the green, for example. The optical excitation source 310 induces fluorescence in the red, which corresponds to an electron transition from the excited state to the ground state. Light from the NV diamond material 320 is directed through the optical filter 350 to filter out light in the excitation band (in the green, for example), and to pass light in the red fluorescence band, which in turn is detected by the detector 340. The optical excitation light source 310, in addition to exciting fluorescence in the diamond material 320, also serves to reset the population of the mₛ=0 spin state of the ground state ³A₂ to a maximum polarization, or other desired polarization.

For continuous wave excitation, the optical excitation source 310 continuously pumps the NV centers, and the RF excitation source 330 sweeps across a frequency range that includes the zero splitting (when the mₛ=±1 spin states have the same energy) photon energy of 2.87 GHz. The fluorescence for an RF sweep corresponding to a diamond material 320 with NV centers aligned along a single direction is shown in FIG. 4 for different magnetic field components Bz along the NV axis, where the energy splitting between the mₛ=−1 spin state and the mₛ=+1 spin state increases with Bz. Thus, the component Bz may be determined. Optical excitation schemes other than continuous wave excitation are contemplated, such as excitation schemes involving pulsed optical excitation, and pulsed RF excitation. Examples of pulsed excitation schemes include Ramsey pulse sequence and spin echo pulse sequence.

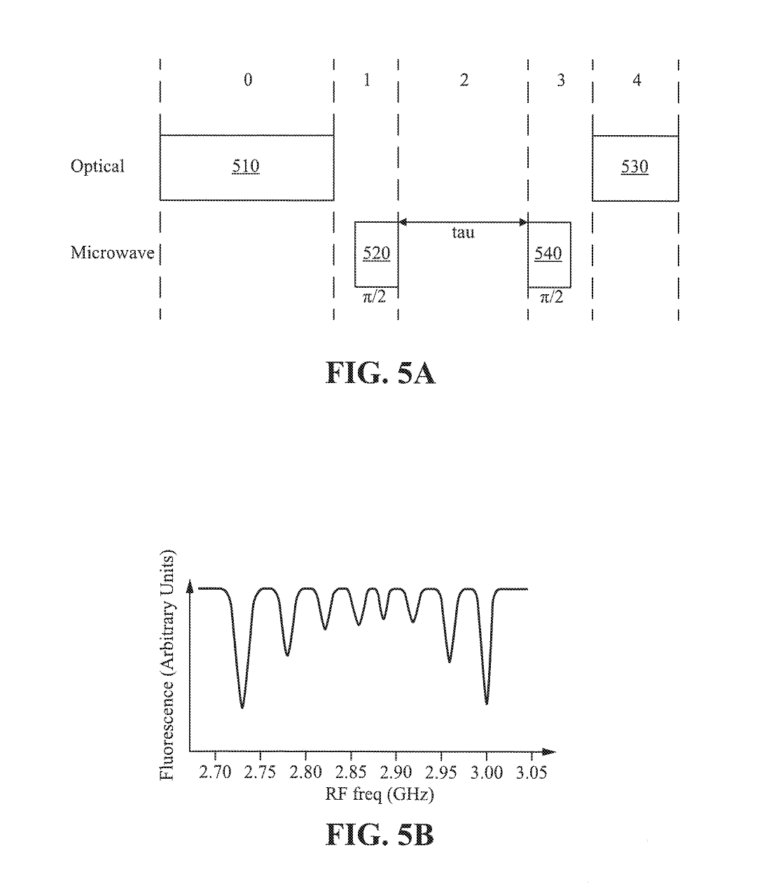

The Ramsey pulse sequence is a pulsed RF-pulsed laser scheme that measures the free precession of the magnetic moment in the diamond material 320 with NV centers, and is a technique that quantum mechanically prepares and samples the electron spin state. FIG. 5A is a schematic diagram illustrating the Ramsey pulse sequence. As shown in FIG. 5A, a Ramsey pulse sequence includes optical excitation pulses and RF excitation pulses over a five-step period. In a first step, during a period 0, a first optical excitation pulse 510 is applied to the system to optically pump electrons into the ground state (i.e., mₛ=0 spin state). This is followed by a first RF excitation pulse 520 (in the form of, for example, a microwave (MW) π/2 pulse) during a period 1. The first RF excitation pulse 520 sets the system into superposition of the mₛ=0 and mₛ=+1 spin states (or, alternatively, the mₛ=0 and mₛ=−1 spin states, depending on the choice of resonance location). During a period 2, the system is allowed to freely precess (and dephase) over a time period referred to as tau (τ). During this free precession time period, the system measures the local magnetic field and serves as a coherent integration. Next, a second RF excitation pulse 540 (in the form of, for example, a MW π/2 pulse) may be applied during a period 3 to project the system back to the mₛ=0 and mₛ=+1 basis. Finally, during a period 4, a second optical pulse 530 may be applied to optically sample the system and a measurement basis is obtained by detecting the fluorescence intensity of the system. The RF excitation pulses applied are provided at a given RF frequency, which correspond to a given NV center orientation.

In general, the diamond material 320 will have NV centers aligned along directions of four different orientation classes, and thus along the four different crystallographic axes of diamond. FIG. 5B illustrates a response curve, specifically fluorescence, as a function of RF frequency for the case where the diamond material 320 has NV centers aligned along directions of four different orientation classes. In this case, the component Bz along each of the different orientations may be determined. FIG. 5B illustrates a spectra with eight electron spin resonances, with two electron spin resonances for each diamond crystallographic axis, the two electron spin resonances corresponding to the mₛ=−1 spin state and the mₛ=+1 spin state. The electron spin resonances are positioned on the FIG. 5B spectra at spectral positions along the RF frequency axis of FIG. 5. In FIG. 5B the eight electron spin resonances are separated to be at different spectral positions along the RF frequency axis.

While FIG. 3 illustrates an NV center magnetic sensor system 300 with NV diamond material 320 with a plurality of NV centers, in general, the magnetic sensor system may instead employ a different magneto-optical defect center material, with a plurality of magneto-optical defect centers. The electron spin state energies of the magneto-optical defect centers shift with magnetic field, and the optical response, such as fluorescence, for the different spin states is not the same for all of the different spin states. In this way, the magnetic field may be determined based on optical excitation, and possibly RF excitation, in a corresponding way to that described above with NV diamond material. The magneto-optical defect centers may be spin centers in silicon carbide, for example, where the substrate may be formed of silicon carbide, or the defect centers may be atomic substitutions in silicon, such as phosphorous in silicon, for example. In general, the electron spin centers may be in magneto-optical defect center material.

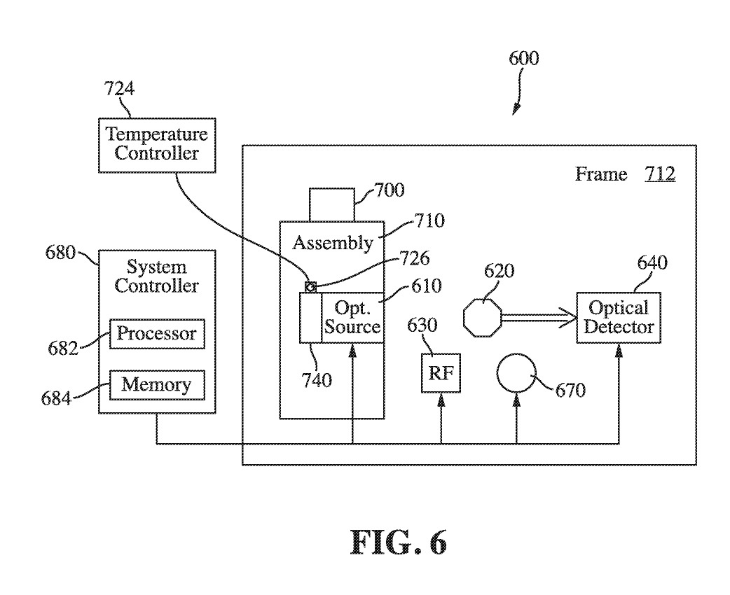

FIG. 6 is a schematic diagram of a magnetic field detection system 600 according to some embodiments. The system 600 includes an optical excitation source assembly 710 comprising an optical excitation source 610, where the optical excitation source 610 directs optical excitation to an NV diamond material 620 with NV centers, or another magneto-optical defect center material with magneto-optical defect centers. An RF excitation source 630 provides RF radiation to the NV diamond material 620. A magnetic field generator 670 generates a magnetic field, which may be detected at the NV diamond material 620 along with external magnetic fields.

The system 600 further includes a system controller 680 arranged to receive a light detection signal from the optical detector 640 and to control the optical excitation source 610, the RF excitation source 630, and magnetic field generator 670, and to perform calculations. The system controller 680 may be a single controller, or may have multiple subcontrollers. For a system controller including multiple subcontrollers, each of the subcontrollers may perform different functions, such as controlling different components of the system 600.

The RF excitation source 630 may be a microwave coil, for example. The RF excitation source 630 may be controlled to emit RF radiation with a photon energy resonant with the transition energy between the ground mₛ=0 spin state and the mₛ=±1 spin states as discussed above with respect to FIG. 3.

The optical excitation source 610 may be a laser or a light emitting diode, for example, which emits light in the green, for example. The optical excitation source 610 induces fluorescence in the red from the NV diamond material 620, where the fluorescence corresponds to an electron transition from the excited state to the ground state. Light from the NV diamond material 620 may be directed to be detected by the optical detector 640. The optical detector 640 may comprise two detectors, for example, one detecting fluorescence light in the red and another detecting light in the green. The optical excitation light source 610, in addition to exciting fluorescence in the NV diamond material 620, may also serve to reset the population of the mₛ=0 spin state of the ground state ³A₂ to a maximum polarization, or other desired polarization.

The system controller 680 may be arranged to receive a light detection signal from the optical detector 640 and to control the optical excitation source 610, the RF excitation source 630, and magnetic field generator 670. The system controller 680 may include a processor 682 and a memory 684, in order to control the operation of the optical excitation source 610, the RF excitation source 630, and the magnetic field generator 670, and to perform calculations. The memory 684, which may include a nontransitory computer readable medium, may store instructions to allow the operation of the optical excitation source 610, the RF excitation source 630, and the magnetic field generator 670 to be controlled. That is, the system controller 680 may be programmed to provide control.

### Optical Excitation Source Assembly

As shown in FIG. 6, the optical excitation source assembly 710 includes the optical excitation source 610 and an active cooling element 740. The active cooling element 740 may be arranged to actively cool the optical excitation source 610. In this regard, active cooling is different from passive cooling, where for example in passive cooling the object to be cooled may be merely thermally connected to a heat sink, for example. The active cooling element 740 may be a thermal electric cooler, for example. The active cooling element 740 may be in thermal contact with the optical excitation source 610, although the active cooling element 740 may not be in direct physical contact with the optical excitation source 610. For example, the optical excitation source 610 may be physically separated from the active cooling element 740, but may be in thermal contact with the active cooling element 740 via a good thermal conductor, such as a metal, for example.

The active cooling element 740 may be arranged to actively cool the optical excitation source 610 apart from any separate actively cooling of other components of the system 600. In particular, the active cooling element 740 may be arranged to actively cool the optical excitation source 610 without actively cooling the RF excitation source 630, the NV diamond material 620, and the optical detector 640. By having the active cooling element 740 cool the optical excitation source 610, and not the RF excitation source 630, the NV diamond material 620, or the optical detector 640, the thermal load on the active cooling element 740 may be reduced.

Further, the RF excitation source 630, the NV diamond material 620, and the optical detector 640 may be arranged so as to not to be cooled by any active cooling element. In some embodiments, however, the RF excitation source 630, the NV diamond material 620, and the optical detector 640 may be cooled by passive cooling, such as by being thermally connected to a heat sink, for example.

The optical excitation source assembly 710 may further include one or more thermometers 726 which are arranged to thermally contact the active cooling element 740. The thermometers 726 provide a temperature indicative of the temperature of the optical excitation source 610. The thermometers 726 may be thermistors, or IR thermometers, for example.

The system may further comprise, in some embodiments, a temperature controller 724. The temperature controller 724 may be configured to receive a temperature signal from the one or more thermometers 726. Based on the temperature signal, the temperature controller 724 controls the active cooling element 740. The temperature controller 724 may be a proportional integral derivative (PID) controller, for example.

The temperature controller 724 may control the active cooling element 740 in some embodiments based on the temperature signal from the one or more thermometers 726 so that the optical excitation source 610 has a temperature which may be maintained at a constant value. The temperature controller 724 may alternatively provide control such that the temperature of the optical excitation source 610 does not remain constant.

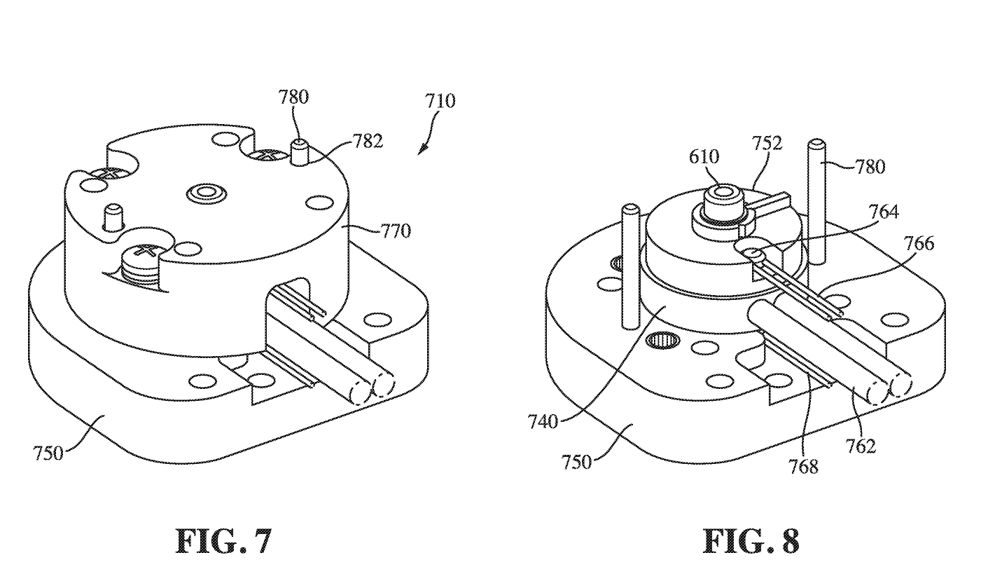

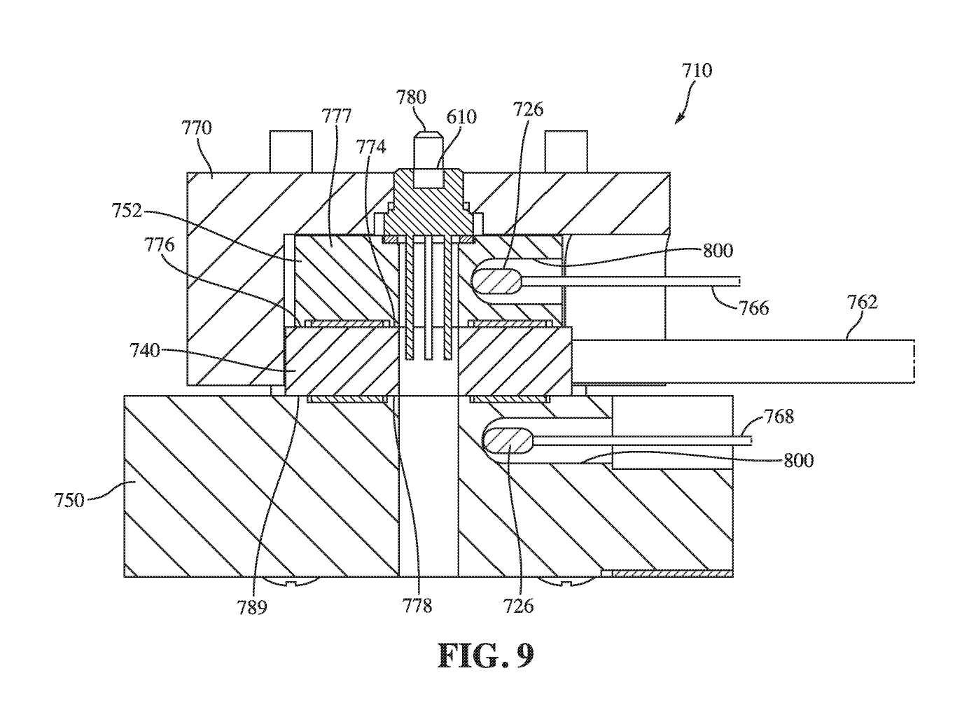

The optical excitation source assembly 710, according to some embodiments may be described with respect to FIGS. 7-9. FIG. 7 is a perspective view of the optical excitation source assembly 710. FIG. 8 is a perspective view of the optical excitation source assembly 710, but with the thermally insulating mount 770 removed to expose the upper heat conducting plate 752. FIG. 9 is a cross-sectional view of the optical excitation source assembly 710.

According to some embodiment, the optical excitation source assembly 710 may include an upper conducting plate 752, a lower conducting plate 750, and an active cooling element 760. The optical excitation source 610, such as a laser diode, may be mounted on, and in thermal contact with, the upper conducting plate 752. The active cooling element 740 may be a thermal electric cooler, for example.

The active cooling element 740 may be arranged between, and in thermal contact with, the lower conducting plate 750, and the upper conducting plate 752. In particular, one side 777 (the upper side in FIG. 9) of the upper conducting plate 752 may be in thermal contact with optical excitation source 610. Another side 776 (the lower side in FIG. 9) of the upper conducting plate 752 may be in thermal contact with a cooling side 774 (the upper side in FIG. 9) of the active cooling element 740. Thus, the cooling of the active cooling element 760 may be transferred to the optical excitation source 610 via thermal conduction by the upper conducting plate 752.

Further, a side 780 (the upper side in FIG. 9) of the lower conducting plate 750 may be in thermal contact with a heat side 778 (the lower side in FIG. 9) of the active cooling element 740. Thus, heat from the active cooling element 740 may be transferred from heat side 778 of the active cooling element 740 by the lower conducting plate 750.

It may be preferable that both of the upper conducting plate 752 and the lower conducting plate 750 be good thermal conductors. In that regard, the upper conducting plate 752 and the lower conducting plate 750 may be metals, for example. For example, the upper conducting plate 752 and the lower conducting plate 750 may be copper, for example.

Further, it preferable that the upper conducting plate 752 and the lower conducting plate 750 be thermally isolated from each other. A function of the upper conducting plate 752 is to provide cooling from the cooling side 774 of the active cooling element 740 to the optical excitation source 610. On the other hand, a function of the lower conducting plate 750 is to conduct heat from the heat side 778 of the active cooling element 740. It may be preferable that the upper conducting plate 752 and the lower conducting plate 750 be thermally isolated from each other so that there is not a thermal short between the upper conducting plate 752 and the lower conducting plate 750 such that heat from the lower conducting plate 750 may be transferred to the upper conducting plate 752.

Further, according to some embodiments the lower conducting plate 750 may be thicker than the upper conducting plate 752. The increased thickness of the lower conducting plate 750 improves its thermal performance.

The one or more thermometers 726 of the optical excitation source assembly 710 may include wiring 766, 768 from the thermometers 726 to the thermal controller 724 (see FIG. 6). The wiring 766, 768 provides an electrical signal from the thermometers 726 indicative of the temperature of the thermometers 726 to the thermal controller 724. The wiring 766 extends from the thermometers 726 contacting the upper conducting plate 752, while the wiring 768 extends from the thermometers 726 contacting the lower conducting plate 750.

According to some embodiments the thermometers 726 may be mounted in mounting holes 800 in the upper conducting plate 752 and the lower conducting plate 750. This arrangement improves the connection to the upper conducting plate 752 and the lower conducting plate 750, and reduce contact of the thermometers 726 with air flow, thus improving the operation of the thermometers 726.

The active cooling element 740 further has wiring 762 extending therefrom, and connected to the controller 724 (see FIG. 6). The controller 724 provides a signal controlling the temperature of the active cooling element 740, where the temperature may be based on the temperature signals from the thermometers 726, in particular to the temperature signals from those of the thermometers 726 thermally contacting the upper conducting plate 752, which in turn thermally contacts the optical excitation source 610.

In order to provide a good thermal contact as desired between certain components, a thermal grease may be applied at the interface between the desired components. For example, thermal grease may be applied between the upper conducting plate 752 and the active cooling element 740, between the lower conducting plate 750 and the active cooling element 740, and between the upper conducting plate 752 and optical excitation source 610.

The lower conducting plate 750 may further include alignment pins 780 to be inserted in holes 782 in the thermally insulating mount 770. The alignment pins 780 aid in aligning the lower conducting plate 750 to the thermally insulating mount 770.

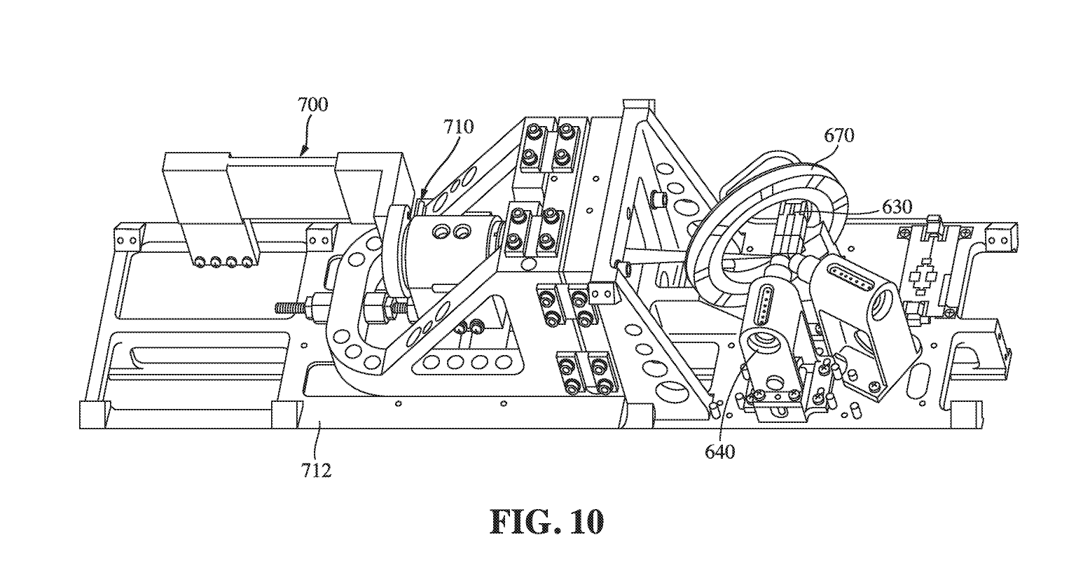

Referring back to FIG. 6, and to FIG. 10, in some embodiments, the system 600 may further include a frame 712. All of the optical excitation source assembly 710, the RF excitation source 630, the NV diamond material 620, and the optical detector 640, may be supported on the frame 712. Further, the system 600 may further include a thermal strap 700 connecting the optical excitation source assembly 710 to the frame 712. Specifically, the thermal strap 700 thermally contacts the lower heat conducting plate 750, which conducts heat from the active cooling element 740 to the frame 712. The thermal strap 700 thermally contacts the lower heat conducting plate 750, while at the same time allowing for decoupling of vibrational forces of the frame 712 from the optical excitation source assembly 710.

### Measurement Collection Process

According to certain embodiments, the system controller 680 controls the operation of the optical excitation source 610, the RF excitation source 630, and the magnetic field generator 670 to perform Optically Detected Magnetic Resonance (ODMR). Specifically, the magnetic field generator 670 may be used to apply a bias magnetic field that sufficiently separates the intensity responses corresponding to electron spin resonances for each of the four NV center orientations. The system controller 680 then controls the optical excitation source 610 to provide optical excitation to the NV diamond material 620 and the RF excitation source 630 to provide RF excitation to the NV diamond material 620. The resulting fluorescence intensity responses for each of the NV axes are collected over time to determine the components of the external magnetic field Bz aligned along directions of the four NV center orientations which respectively correspond to the four diamond lattice crystallographic axes of the NV diamond material 620, which may then be used to calculate the estimated vector magnetic field acting on the system 600. The excitation scheme utilized during the measurement collection process (i.e., the applied optical excitation and the applied RF excitation) may be any appropriate excitation scheme. For example, the excitation scheme may utilize continuous wave (CW) magnetometry, pulsed magnetometry, and variations on CW and pulsed magnetometry (e.g., pulsed RF excitation with CW optical excitation). In cases where Ramsey pulse RF sequences are used, pulse parameters π and τ may be optimized using Rabi analysis and FID-Tau sweeps prior to the collection process, as described in, for example, U.S. patent application Ser. No. 15/003,590 entitled “APPARATUS AND METHOD FOR HIGH SENSITIVITY MAGNETOMETRY MEASUREMENT AND SIGNAL PROCESSING IN A MAGNETIC DETECTOR SYSTEM” filed Jan. 21, 2016, incorporated by referenced in its entirety. The pulse parameters π and τ may also be optimized using another optimization scheme.

Embodiments have been described in detail with particular reference to preferred embodiments, but it will be understood by those skilled in the art that variations and modifications can be effected within the spirit and scope of this disclosure.

What is claimed is:

1. A system for magnetic detection of an external magnetic field, comprising:
a magneto-optical defect center material comprising a plurality of magneto-optical defect centers;
a radio frequency (RF) excitation source;
an optical excitation source assembly comprising an optical excitation source;
a system controller configured to:
control the RF excitation source to provide RF excitation to the magneto-optical defect center material; and
control the optical excitation source to provide optical excitation to the magneto-optical defect center material; and
an optical detector configured to receive an optical signal based on light emitted by the magneto-optical defect center material due to the RF excitation and the optical excitation provided to the magneto-optical defect center material,
wherein the optical excitation source assembly comprises an active cooling element arranged to actively cool the optical excitation source without cooling the RF excitation source, the magneto-optical defect center material, or the optical detector.

2. The system of claim 1, wherein the optical excitation source comprises a laser.

3. The system of claim 1, wherein the magneto-optical defect center material comprising a diamond nitrogen vacancy material comprising a plurality of nitrogen vacancy defect centers.

4. The system of claim 1, wherein the RF excitation source, the magneto-optical defect center material, and the optical detector are not arranged to be cooled by any active cooling element.

5. The system of claim 1, further comprising a frame, wherein the optical excitation source assembly, the RF excitation source, the magneto-optical defect center material, and the optical detector, are all supported on the frame.

6. The system of claim 5, further comprising a thermal strap connecting the optical excitation source assembly and the frame.

7. The system of claim 1, wherein the active cooling element comprises a thermal electric cooler.

8. The system of claim 1, wherein the optical excitation source assembly further comprises an upper heat conducting plate, wherein the optical excitation source is mounted on, and in thermal contact with, one side of the upper heating conducting plate, and a cooling side of the active cooling element is in thermal contact with an other side of the upper heating conducting plate.

9. The system of claim 8, wherein the upper heat conducting plate comprises a metal.

10. The system of claim 8, wherein the optical excitation source assembly further comprises a lower heat conducting plate in thermal contact with a heat side of the active cooling element.

11. The system of claim 10, wherein the lower heat conducting plate comprises a metal.

12. The system of claim 10, wherein the lower heat conducting plate is thermally isolated from the upper heat conducting plate.

13. The system of claim 10, wherein the optical excitation source assembly further comprises a thermally insulating mount enclosing the upper heat conducting plate and the active cooling element, and fixed to the lower heat conducting plate.

14. The system of claim 10, wherein the upper heat conducting plate is thinner than the lower heat conducting plate.

15. The system of claim 1, wherein the optical excitation source assembly further comprises one or more thermometers thermally contacting the optical excitation source.

16. The system of claim 15, wherein the one or more thermometers comprise one or more thermistors.

17. The system of claim 15, further comprises a temperature controller configured to receive a temperature signal from the one or more thermometers, and to control the active cooling element based on the received temperature signal.

18. The system of claim 17, where the temperature controller is a proportional integral derivative (PID) controller.

19. The system of claim 17, wherein the temperature controller is configured to control the active cooling element based on the received temperature signal to maintain the optical excitation source at a constant temperature.

20. A system for magnetic detection of an external magnetic field, comprising:
a magneto-optical defect center material comprising a plurality of magneto-optical defect centers;
a radio frequency (RF) excitation source;
an optical excitation source assembly comprising an optical excitation source;
a system controller configured to:
control the RF excitation source to provide RF excitation to the magneto-optical defect center material; and
control the optical excitation source to provide optical excitation to the magneto-optical defect center material; and
an optical detector configured to receive an optical signal based on light emitted by the magneto-optical defect center material due to the RF excitation and the optical excitation provided to the magneto-optical defect center material,
wherein the optical excitation source assembly further comprises:
a thermal electric cooler arranged to actively cool the optical excitation source without cooling the RF excitation source, the magneto-optical defect center material, or the optical detector;
one or more thermometers thermally contacting the optical excitation source; and
a temperature controller configured to receive a temperature signal from the one or more thermometers, and to control the thermal electric cooler based on the received temperature signal.
